(19) United States
(12) Patent Application Publication
(10) Pub. No.: US 2015/0194916 A1
(43) Pub. Date: Jul. 9, 2015

(54) APPARATUS FOR DRIVING MOTOR AND CONTROLLING METHOD THEREOF

(71) Applicant: SAMSUNG ELECTRO-MECHANICS CO., LTD., Gyeonggi-Do (KR)

(72) Inventors: Nam Hong JANG, Gyeonggi-Do (KR); Joung Ho SON, Gyeonggi-Do (KR); Hong Chul SHIN, Gyeonggi-Do (KR)

(73) Assignee: SAMSUNG ELECTRO-MECHANICS CO., LTD., Gyeonggi-Do (KR)

(21) Appl. No.: 14/591,633

(22) Filed: Jan. 7, 2015

(30) Foreign Application Priority Data
Jan. 7, 2014 (KR) 10-2014-0001850

(51) Int. Cl. H02P 6/24; G01R 31/34

(52) U.S. Cl. CPC H02P 6/24; G01R 31/343

(57) ABSTRACT

Embodiments of the invention provide an apparatus for driving a motor, in which the apparatus includes a rectifier configured to rectify an input voltage to generate a driving voltage, and a motor driver configured to apply the driving voltage to the respective phases of the motor through a switching operation. The apparatus further includes a controller configured to control a pulse width modulation signal for controlling the switching operation of the motor driver, to decide whether or not driving of the motor is stopped depending on whether or not an over-voltage is generated in the input voltage based on an output voltage sensed by the rectifier and to decide whether or not the motor is again driven or whether or not the driving of the motor is completely stopped by deciding whether or not the input voltage returns to a normal voltage or whether or not the over-voltage is again generated within a predetermined time according to the number of generated over-voltages.

### CROSS REFERENCE TO RELATED APPLICATION

This application claims the benefit of and priority under 35 U.S.C. §119 to 35 U.S.C. §119 to Korean Patent Application No. KR 10-2014-0001850, entitled “APPARATUS FOR DRIVING MOTOR AND CONTROLLING METHOD THEREOF,” filed on Jan. 7, 2014, which is hereby incorporated by reference in its entirety into this application.

### BACKGROUND

1. Field of the Invention

The present invention relates to an apparatus for driving a motor and a controlling method thereof.

2. Description of the Related Art

In a switched reluctance motor (hereinafter, referred to as an “SRM”), which is a motor having a form in which it has a switching control apparatus coupled thereto, both of a stator and a rotor have a salient pole type structure.

Particularly, since only a stator part has a winding wound therearound and a rotor part does not include any type winding or permanent magnet, a structure of the SRM is simple.

Due to this structural feature, the SRM has a significant advantage in terms of manufacturing and production, and has good start-up characteristics and a large torque, similar to a direct current motor. In addition, the SRM requires less maintenance and has excellent characteristics in terms of a torque per unit volume, efficiency, and a rating of a converter, as non-limiting examples, such that the use of the SRM has gradually increased in various fields.

The SRM as described above may have various types, such as a single-phase, a two-phase, or a three-phase, as non-limiting examples. Among others, the two-phase SRM has a driving circuit simpler than that of the three-phase SRM, such that it has been significantly prominent in applications, such as a fan, a blower, or a compressor, as non-limiting examples.

However, in the case in which an instantaneous over-voltage is applied in an input voltage to a control circuit of the SRM according to conventional art, for example, Korean Patent Publication No. 2001-0068827, a protection function for preventing the control circuit from being electrically damaged has not been applied. Therefore, electrical damage has occurred in electrical components or devices configuring the control circuit due to an instantaneous voltage variation occurring due to power failure in places such as India or Africa, for example, belonging to a region in which the supply of power is bad.

### SUMMARY

Accordingly, embodiments of the invention have been made to provide an apparatus for driving a motor capable of preventing electrical damage to a control circuit of a switched reluctance motor (SRM) by controlling driving of the SRM through a process of preventing damage to a system due to an instantaneous over-voltage in the case in which the instantaneous over-voltage is generated in an input voltage applied for driving the SRM, and a controlling method thereof.

According to at least one embodiment, there is provided an apparatus for driving a motor, in which the apparatus includes a rectifier configured to rectify an input voltage (AC) to generate a driving voltage, a motor driver configured to apply the driving voltage to the respective phases of the motor through a switching operation, and a controller configured to generate a pulse width modulation (PWM) signal for controlling the switching operation of the motor driver, to decide whether or not driving of the motor is stopped depending on whether or not an over-voltage is generated in the input voltage based on an output voltage sensed by the rectifier, and to decide whether or not the motor is again driven or whether or not the driving of the motor is completely stopped by deciding whether or not the input voltage returns to a normal voltage or whether or not the over-voltage is again generated within a predetermined time according to the number of generated over-voltages.

According to at least one embodiment, the rectifier includes a rectifier circuit configured to generate the driving voltage through a smoothing capacitor and a bridge rectifier circuit, and a voltage divider circuit configured to divide the driving voltage of the rectifier circuit through a resistor circuit to generate the output voltage.

According to at least one embodiment, the controller is further configured to decide whether or not the motor is again driven depending on whether or not the normal voltage is applied in the input voltage or whether or not the driving of the motor is completely stopped depending on whether or not the over-voltage is again generated within the predetermined time, according to a comparison result between the number of generated over-voltages and a preset reference number, in the case in which the over-voltage is generated, such that the driving of the motor is stopped.

According to at least one embodiment, the controller is further configured to compare a magnitude of the input voltage with that of a first preset reference voltage based on the output voltage and decide whether or not a time in which the input voltage is continuously applied is a first preset reference time or more in the case in which the magnitude of the input voltage is larger than that of the first preset reference voltage, thereby deciding whether or not the motor is stopped.

According to at least one embodiment, the controller is further configured to maintain a state in which the driving of the motor is stopped for a predetermined time and then decide whether or not the motor is again driven depending on a comparison result between the input voltage and a second preset reference voltage in the case in which the number of generated over-voltages is not larger than the preset reference number and to decide whether or not the driving of the motor is completely stopped depending on whether or not the over-voltage is again generated within a second preset reference time in the case in which the number of generated over-voltages is larger than the preset reference number.

According to at least one embodiment, the controller is further configured to completely stop the driving of the motor and again drive the motor only in the case in which a predetermined input signal is applied from the outside, in the case in which the over-voltage is again generated within the second preset reference time.

According to at least one embodiment, the controller is further configured to control whether or not the motor is again driven or whether or not the driving of the motor is completely stopped through the PWM signal in the case in which the over-voltage is generated.

According to at least one embodiment, the controller further includes a PWM signal generating module generating the PWM signal for controlling the switching operation of the motor driver, and is further includes a controller configured to control whether or not the motor is again driven or whether or not the driving of the motor is completely stopped depending on whether or not the over-voltage is generated in the input voltage and whether or not the over-voltage is again generated within the predetermined time through a control of the PWM signal generating module.

According to another embodiment of the invention, there is provided a controlling method of an apparatus for driving a motor, in which the method includes the steps of an over-voltage generation deciding step of deciding whether or not the driving of the motor is stopped depending on whether or not an over-voltage is generated in an input voltage based on an output voltage sensed by a rectifier; a step of comparing the number of generated over-voltages with a preset reference number, and a motor driving controlling step of controlling whether or not the motor is again driven or whether or not the driving of the motor is completely stopped by deciding whether or not the input voltage returns to a normal voltage or whether or not the over-voltage is again generated within a predetermined time depending on a comparison result between the number of generated over-voltages and the preset reference number.

According to at least one embodiment, the over-voltage generation deciding step includes a step of generating a driving voltage by rectifying the input voltage through a smoothing capacitor and a bridge rectifier circuit, and a step of sensing the output voltage by dividing the driving voltage through a resistor circuit.

According to at least one embodiment, the over-voltage generation deciding step includes a step of comparing a magnitude of the input voltage with that of a first preset reference voltage based on the output voltage, a step of deciding whether or not a time in which the input voltage is continuously applied is a first preset reference time or more in the case in which the magnitude of the input voltage is larger than that of the first preset reference voltage, and a step of counting an over-voltage generation time and the number of generated over-voltages and stopping the driving of the motor in the case in which the time in which the input voltage is continuously applied is the first preset reference time or more.

According to at least one embodiment, the motor driving controlling step includes a step of deciding whether or not the motor is again driven by comparing the input voltage with a second preset reference voltage in the case in which the number of generated over-voltages is smaller than the preset reference number, and a step of deciding whether or not the driving of the motor is completely stopped by comparing the over-voltage generation time in which the over-voltage is again generated with a second preset reference time in the case in which the number of generated over-voltages is larger than the preset reference number.

According to at least one embodiment, the step of deciding whether or not the motor is again driven includes a step of maintaining a state in which the driving of the motor is stopped for a predetermined time, a step of comparing the input voltage with the second preset reference voltage based on the output voltage, and a step of again driving the motor in the case in which the input voltage is smaller than the second preset reference voltage.

According to at least one embodiment, the step of deciding whether or not the driving of the motor is completely stopped includes a step of comparing the over-voltage generation time with the second preset reference time, and a step of deciding whether or not a predetermined input signal is applied from the outside in the case in which the over-voltage generation time is smaller than the second preset reference time.

According to at least one embodiment, the step of deciding whether or not the driving of the motor is completely stopped further includes, in the case in which the predetermined input signal is applied from the outside, a step of initializing the number of generated over-voltages and the over-voltage generation time, and again driving the motor.

According to at least one embodiment, the step of deciding whether or not the driving of the motor is completely stopped further includes, in the case in which the over-voltage generation time is larger than the second preset reference time, a step of initializing the number of generated over-voltages and the over-voltage generation time, a step of maintaining the state in which the driving of the motor is stopped for the predetermined time, a step of deciding whether or not the motor is again driven by comparing the input voltage with that of the second preset reference voltage based on the output voltage, and a step of again driving the motor in the case in which the input voltage is smaller than the second preset reference voltage.

Various objects, advantages and features of the invention will become apparent from the following description of embodiments with reference to the accompanying drawings.

### BRIEF DESCRIPTION OF DRAWINGS

These and other features, aspects, and advantages of the invention are better understood with regard to the following Detailed Description, appended Claims, and accompanying Figures. It is to be noted, however, that the Figures illustrate only various embodiments of the invention and are therefore not to be considered limiting of the invention's scope as it may include other effective embodiments as well.

FIG. 1 is a block diagram showing an apparatus for driving a motor according to an embodiment of the invention.

FIG. 2 is a circuit diagram showing a configuration of a rectifier according to an embodiment of the invention.

FIG. 3 is a diagram showing that an instantaneous over-voltage is applied in an input voltage according to an embodiment of the invention.

FIGS. 4A and 4B are diagrams showing a driving state of a switched reluctance motor (SRM) in the case in which an instantaneous over-voltage is generated in an input voltage according to an embodiment of the invention.

FIG. 5 is a flow chart schematically showing a controlling method of an apparatus for driving a motor according to an embodiment of the invention.

FIG. 6 is a diagram showing a step of deciding whether or not driving of a motor is stopped depending on whether or not an over-voltage is generated in the controlling method of an apparatus for driving a motor according to an embodiment of the invention.

FIG. 7 is a diagram showing a step of deciding whether or not the motor is again driven or whether or not driving of the motor is completely stopped in the controlling method of an apparatus for driving a motor according to an embodiment of the invention.

FIG. 8 is a flow chart showing the controlling method of an apparatus for driving a motor according to an embodiment of the invention.

### DETAILED DESCRIPTION

Advantages and features of the present invention and methods of accomplishing the same will be apparent by referring to embodiments described below in detail in connection with the accompanying drawings. However, the present invention is not limited to the embodiments disclosed below and may be implemented in various different forms. The embodiments are provided only for completing the disclosure of the present invention and for fully representing the scope of the present invention to those skilled in the art.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. Like reference numerals refer to like elements throughout the specification.

Hereinafter, various embodiments of the present invention will be described in detail with reference to the accompanying drawings.

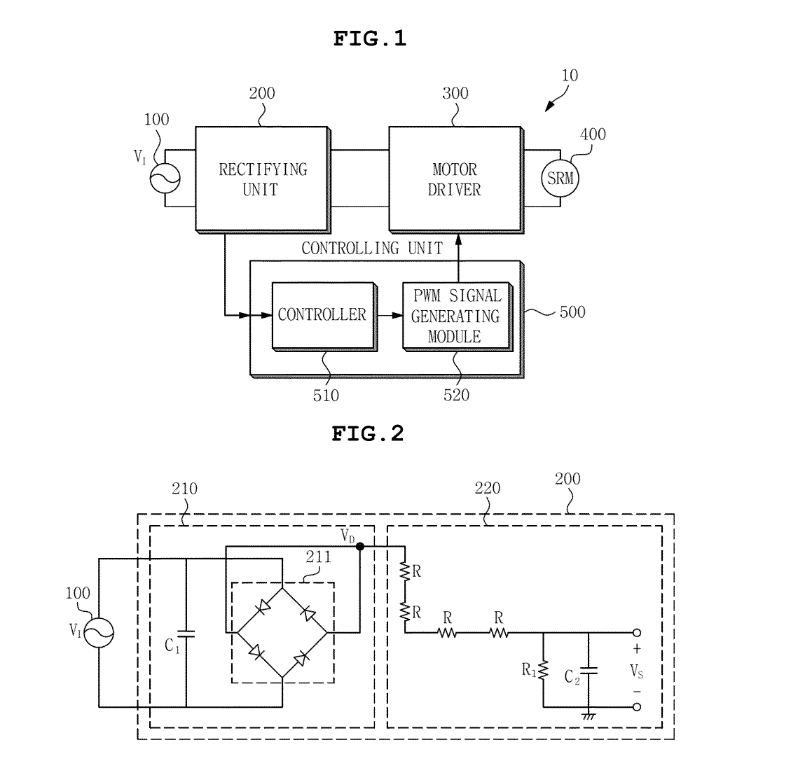

FIG. 1 is a diagram illustrating a camera module of an auto focus function to which an apparatus for driving a voice coil motor actuator according to a first embodiment of the invention is applied, and FIG. 2 is a diagram illustrating the apparatus for driving a voice coil motor actuator according to the first embodiment of the invention.

Hereinafter, an apparatus for driving a motor and a controlling method thereof according to various embodiments of the invention will be described in detail with reference to the accompanying drawings. According to at least one embodiment, the motor includes, for example, a switched reluctance motor (hereinafter, referred to as an SRM), and an instantaneous over-voltage includes, for example, the case in which a magnitude of a power supply voltage (AC) applied in an input voltage satisfies a predetermined condition.

FIG. 1 is a block diagram showing an apparatus for driving a motor according to an embodiment of the invention, and FIG. 2 is a circuit diagram showing a configuration of a rectifier according to an embodiment of the invention.

As shown in FIG. 1, an apparatus 10 for driving a motor according to an embodiment of the invention includes a rectifying unit 200 (hereinafter referred to as a “rectifier 200”), a motor driver 300, and a controlling unit 500 (hereinafter referred to as a “controller 500”).

According to at least one embodiment, the rectifier 200 includes a rectifying circuit 210 (hereinafter referred to as a “rectifier circuit 210”) rectifying an input voltage V_{I} (AC) to generate a driving voltage V_{D} and generating the driving voltage V_{D} through a smoothing capacitor C₁ smoothing the input voltage V_{I}, and a bridge rectifying circuit 211 (hereinafter referred to as a “bridge rectifier circuit 211”) rectifying the smoothed input voltage 100 and a voltage dividing circuit 220 (hereinafter referred to as a “voltage divider circuit 220”) dividing the driving voltage V_{D} of the rectifier circuit 210 through a resistor circuit to generate an output voltage V_{S}, wherein the resistor circuit includes an output resistor R₁ (having a resistance of 27 kΩ) connected in parallel with four resistors R (having a resistance of 750 kΩ) connected in series with each other and a capacitor C₂ connected to the output resistor R₁ (having the resistance of 27 kΩ) and maintaining a predetermined output voltage V_{S}.

According to at least one embodiment, the motor driver 300 applies the driving voltage V_{D} to a winding wound around a stator of the SRM 400 through a switching operation using a plurality of switching devices (for example, insulated gate bipolar mode transistors (IGBTs)) to sequentially excite the respective phases of the SRM 400, thereby rotating a rotor (not shown) in one direction by a reluctance torque generated by a change in a reluctance depending on relative positions between the rotor (not shown) and the excited stator due to magnetic force generated in the respective phases that are excited.

According to at least one embodiment, the controller 500 generates a pulse width modulation (PWM) signal for controlling the switching operation of the motor driver 300, decides whether or not driving of the SRM is stopped depending on whether or not an over-voltage is generated in the input voltage 100 based on the output voltage V_{S} sensed by the rectifier 200, and decides whether or not the motor is again driven depending on whether or not a normal voltage is applied in the input voltage 100 or whether or not the driving of the motor is completely stopped depending on whether or not the over-voltage is again generated within a predetermined time, according to the number of generated over-voltages and a preset reference number in the case in which the over-voltage is generated, such that the driving of the SRM 400 is stopped.

According to at least one embodiment, the controller 500 compares a magnitude of the input voltage 100 with that of a first preset reference voltage based on the output voltage V_{S} and decide whether or not a time in which the input voltage 100 is continuously applied is a first preset reference time or more in the case in which the magnitude of the input voltage 100 is larger than that of the first preset reference voltage, thereby deciding whether or not the SRM 400 is stopped.

According to at least one embodiment, the controller 500 maintains a state in which the driving of the SRM 400 is stopped for a predetermined time and then decide whether or not the SRM 400 is again driven depending on a comparison result between the input voltage and a second preset reference voltage in the case in which the number of generated over-voltages is not larger than the preset reference number, decides whether or not the driving of the SRM 400 is completely stopped depending on whether or not the over-voltage is again generated within a second preset reference time in the case in which the number of generated over-voltages is larger than the preset reference number, and controls whether or not the SRM 400 is again driven or whether or not the driving of the SRM 400 is completely stopped through the PWM signal in the case in which the over-voltage is generated.

Further, according to at least one embodiment, the controller 500 completely stops the driving of the SRM 400 and again drives the SRM 400 only in the case in which a predetermined input signal is applied from the outside, in the case in which the over-voltage is again generated within the second preset reference time, and includes a PWM signal generating module 520 generating the PWM signal for controlling the switching operation of the motor driver 300 and a controller 510 controlling whether or not the SRM 400 is again driven or whether or not the driving of the SRM 400 is completely stopped depending on whether or not the over-voltage is generated in the input voltage 100 and whether or not the over-voltage is again generated within the predetermined time through a control of the PWM signal generating module 520.

As described above, the apparatus 10 for driving a motor according to an embodiment of the invention controls the driving of the SRM through a process of preventing damage to a system due to the instantaneous over-voltage in the case in which the instantaneous over-voltage is generated in the input voltage 100 applied for driving the SRM, thereby making it possible to secure driving stability of the SRM and durability of components.

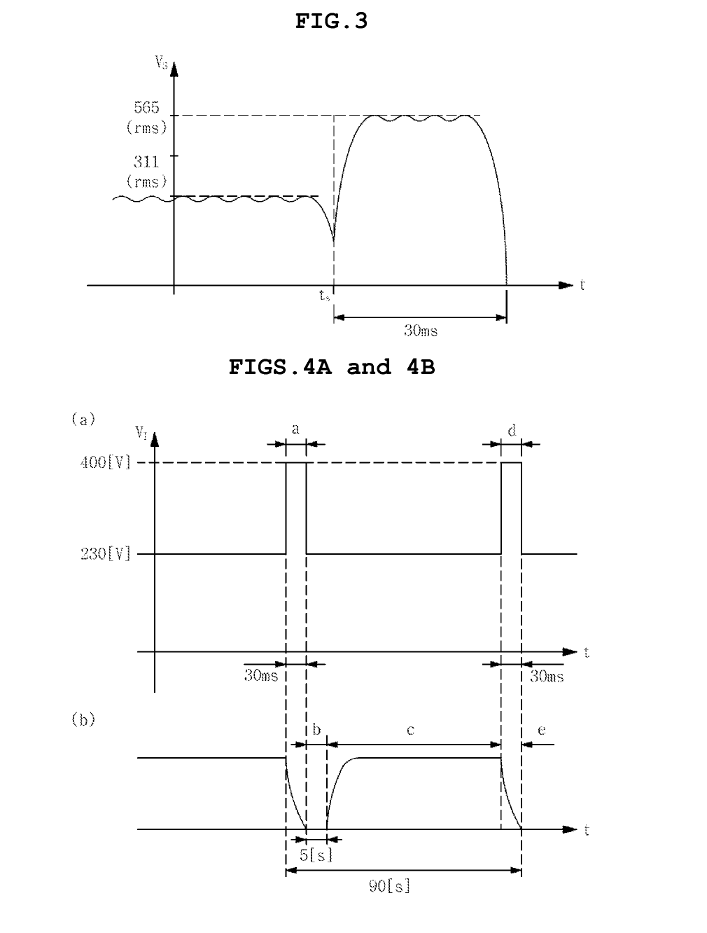

Hereinafter, a controlling method of an apparatus for driving a motor (SRM) in the case in which an instantaneous over-voltage is generated in an input voltage of the motor (SRM) will be described in more detail with reference to FIGS. 3 to 8.

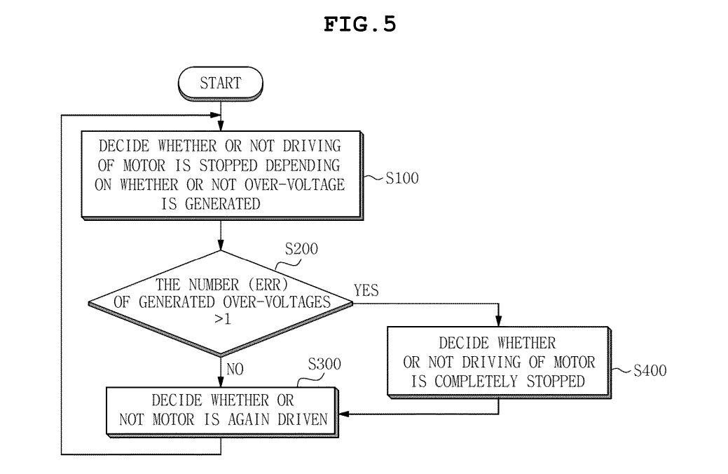

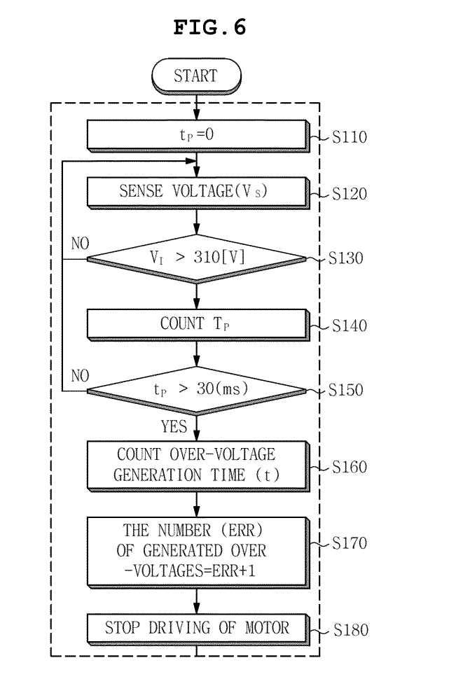

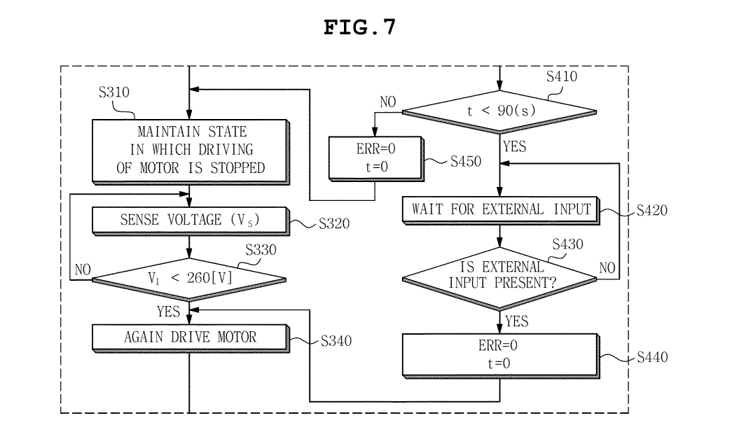

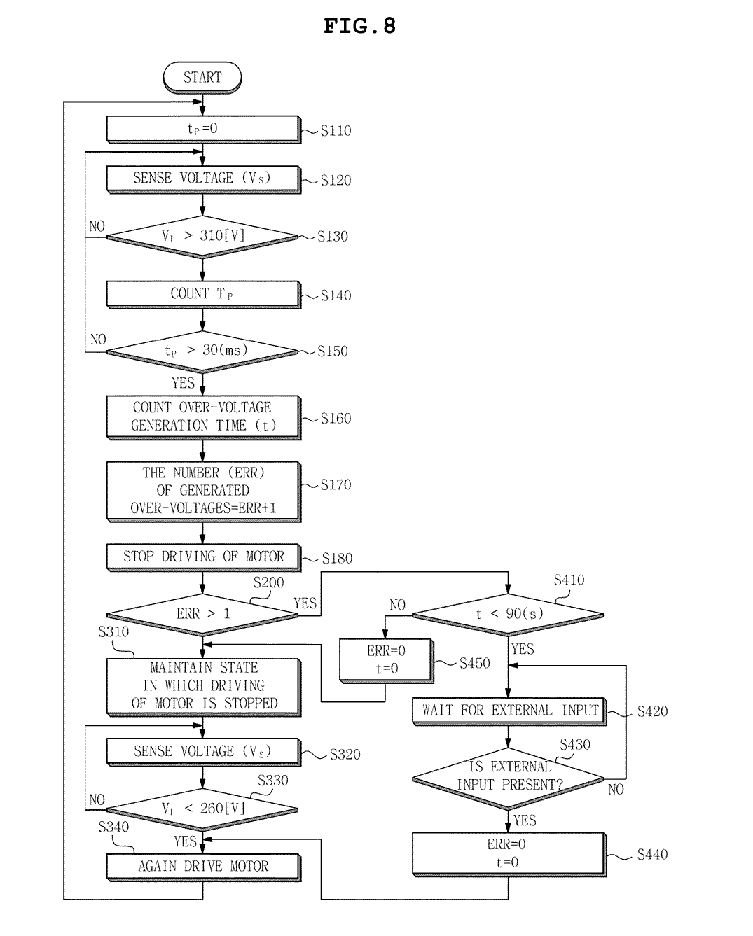

FIG. 3 is a diagram showing that an instantaneous over-voltage is applied in an input voltage according to an embodiment of the invention; FIGS. 4A and 4B are diagrams showing a driving state of an SRM in the case in which an instantaneous over-voltage is generated in an input voltage according to an embodiment of the invention; FIG. 5 is a flow chart schematically showing a controlling method of an apparatus for driving a motor according to an embodiment of the invention; FIG. 6 is a diagram showing a step of deciding whether or not driving of a motor is stopped depending on whether or not an over-voltage is generated in the controlling method of an apparatus for driving a motor according to an embodiment of the invention; FIG. 7 is a diagram showing a step of deciding whether or not the motor is again driven or whether or not driving of the motor is completely stopped in the controlling method of an apparatus for driving a motor according to an embodiment of the invention; and FIG. 8 is a flow chart showing the controlling method of an apparatus for driving a motor according to an embodiment of the invention.

As shown in FIG. 5, the controlling method of an apparatus for driving a motor (SRM) according to an embodiment of the invention includes 1) an over-voltage generation deciding step (S100) of deciding whether or not the driving of the motor (SRM) is stopped depending on whether or not the over-voltage is generated in the input voltage V_{I} based on the output voltage Vs sensed by the rectifier 200, 2) a step (S200) of comparing the number of generated over-voltages with a preset reference number, and 3) a motor (SRM) driving controlling step of controlling whether or not the motor (SRM) is again driven (S300) or whether or not the driving of the motor (SRM) is completely stopped (S400) by deciding whether or not the input voltage 100 V_{I} returns to a normal voltage or whether or not the over-voltage is again generated within the predetermined time depending on a comparison result between the number of generated over-voltages and the preset reference number.

As shown in FIG. 6, in the over-voltage generation deciding step (S100) of deciding whether or not the driving of the motor (SRM) is stopped depending on whether or not the over-voltage is generated in the input voltage 100 V_{I} based on the output voltage V_{S} sensed by the rectifier 200, the controller 500 performs 1) steps (S120 and S130) of comparing a magnitude of the input voltage 100 V_{I} with that of the first preset reference voltage (e.g., 310V according to at least one embodiment of the invention) based on the output voltage V_{S}, 2) a step of counting the time t_{P} in which the input voltage 100 V_{I} is continuously applied (S140) and deciding whether or not the time t_{P} is the first preset reference time (e.g., 30 ms according to at least one embodiment of the invention) or more in the case in which the magnitude of the input voltage 100 V_{I} is larger than that of the first preset reference voltage, and 3) steps (S160 and S170) of counting an over-voltage generation time t and the number ERR of generated over-voltages and stopping the driving of the motor in the case in which the time t_{P} is the first preset reference time or more, and the time t_{P} is initialized (S110) in the case in which a predetermined condition is satisfied after the driving of the motor (SRM) is stopped, such that the motor is again driven. The over-voltage generation time t is continuously counted until it is initialized in the following step.

Thus, as shown in FIG. 3, in the case in which an over-voltage (565 root mean square (hereinafter, referred to as “RMS”)) is applied in a state in which a normal voltage (311RMS) is applied in the output voltage V_{S}, the controller 500 1) compares a magnitude of the input voltage 100 V_{I} (400V) with that of the first preset reference voltage (310V) based on the over-voltage (565RMS) sensed in the output voltage V_{S}, 2) counts the time t_{P} in which the input voltage 100 V_{I} is continuously applied since the input voltage 100 V_{I} (400V) is larger than the first preset reference voltage (310V), and 3) stops generation of the PWM signal for driving a switching device (not shown) of the motor driver 300 through the PWM signal generating module 520 in the case in which the time t_{P} is larger than the first preset reference time (30 ms), thereby stopping the driving of the motor (SRM) and counting the over-voltage generation time t and the number ERR of generated over-voltages.

As shown in FIGS. 7 and 8, in the case in which number ERR of generated over-voltages is smaller than the preset reference number (e.g., 1 according to at least one embodiment of the invention), in the step of controlling whether or not the motor (SRM) is again driven (S300) depending on whether or not the input voltage 100 V_{I} returns to the normal voltage, the controller 500 performs 1) a step (S310) of maintaining a state in which the driving of the motor (SRM) is stopped for a predetermined time (e.g., 5S according to at least one embodiment of the invention), 2) a step (S330) of comparing the input voltage 100 V_{I} with the second preset reference voltage (e.g., 260V according to at least one embodiment of the invention) based on the output voltage V_{S} (S320), and 3) a step (S340) of again driving the motor (SRM) in the case in which the input voltage 100 V_{I} is smaller than the second preset reference voltage.

In addition, in the case in which the number ERR of generated over-voltages is larger than the preset reference number (e.g., 1 according to at least one embodiment of the invention), in the step of controlling whether or not the driving of the motor (SRM) is completely stopped (S400) by deciding whether or not the over-voltage is again generated within the predetermined time (e.g., 90S according to at least one embodiment of the invention), the controller 500 performs 1) a step (S410) of comparing the over-voltage generation time t with the second preset reference time (e.g., 90S according to at least one embodiment of the invention), 2) steps (S420 and S430) of deciding whether or not a predetermined input signal is applied from the outside in the case in which the over-voltage generation time t is smaller than the second preset reference time, and 3) a step (S440) of initializing the number ERR of generated over-voltages and the over-voltage generation time t in the case in which the predetermined input signal is applied from the outside. Here, the predetermined input signal may be a signal by a specific button of a remote controller of a user.

Further, in the case in which the over-voltage generation time t is larger than the second preset reference time, the controller 500 performs 1) a step (S450) of initializing the number ERR of generated over-voltages and the over-voltage generation time t, 2) a step (S310) of maintaining a state in which the driving of the motor is stopped, 3) steps (S320 and S330) of deciding whether or not the motor is again driven by comparing the input voltage 100 with the second preset reference voltage based on the output voltage, and 4) a step (S340) of again driving the motor in the case in which the input voltage 100 is smaller than the second preset reference voltage.

Thus, as shown in FIGS. 4A and 4B, the controller 500 stops the driving of the motor (SRM) for 5S (section b) in the case in which the instantaneous over-voltage (400V) is applied for 30 ms (section a) in a state in which the normal voltage (230V) is applied in the input voltage 100, again drive the motor (SRM) (section c) in the case in which the input voltage 100 returns to the normal voltage, and stop the driving of the motor and then maintain a state in which the driving of the motor (SRM) is stopped (section e) as long as a separate specific input is not present from the outside when the instantaneous over-voltage (400V) is applied for 30 ms within 90S (section d) after the over-voltage is applied.

As described above, in the controlling method of an apparatus for driving a motor according to an embodiment of the invention, reliability for the driving of the SRM is secured even under an instantaneous voltage variation due to power failure, for example, in a region in which the supply of power is bad through a two-step process of sensing whether or not the instantaneous over-voltage is generated in the input voltage for driving the SRM in real time to stop the driving of the SRM under a predetermined reference in the case in which the instantaneous over-voltage is generated in the input voltage and controlling whether or not the motor is again driven or whether or not the driving of the motor is completely stopped depending on whether or not the input voltage returns to the normal voltage or whether or not the over-voltage is again generated within the predetermined time.

In addition, in the case in which the instantaneous over-voltage is generated twice in the input voltage for driving the SRM within the predetermined time, the SRM is repeatedly again driven due to the generation of the instantaneous over-voltage and the return of the input voltage to the normal voltage through a complete stop step of stopping the driving of the SRM as long as a specific external input by the user is not present. Therefore, electrical stress, a deterioration phenomenon, for example, of components configuring a control circuit of the SRM are prevented in advance, thereby making it possible to maintain stability in driving the SRM and durability of the components of the control circuit.

As set forth above, with the apparatus for driving a motor and a controlling method thereof according to an embodiment of the invention, the driving of the SRM is controlled through a process of preventing damage to a system due to the instantaneous over-voltage in the case in which the instantaneous over-voltage is generated in the input voltage applied for driving the SRM, thereby making it possible to secure driving stability of the SRM and durability of components.

In addition, reliability for the driving of the SRM is secured even under an instantaneous voltage variation due to power failure, for example, in a region in which the supply of power is bad through a two-step process of sensing whether or not the instantaneous over-voltage is generated in the input voltage for driving the SRM in real time to stop the driving of the SRM under a predetermined reference in the case in which the instantaneous over-voltage is generated in the input voltage and controlling whether or not the motor is again driven or whether or not the driving of the motor is completely stopped depending on whether or not the input voltage returns to the normal voltage or whether or not the over-voltage is again generated within the predetermined time.

Further, in the case in which the instantaneous over-voltage is generated twice in the input voltage for driving the SRM within the predetermined time, the SRM is repeatedly again driven due to the generation of the instantaneous over-voltage and the return of the input voltage to the normal voltage through a complete stop step of stopping the driving of the SRM as long as a specific external input by the user is not present. Therefore, electrical stress, a deterioration phenomenon, for example, of components configuring a control circuit of the SRM are prevented in advance, thereby making it possible to maintain stability in driving the SRM and durability of the components of the control circuit.

Terms used herein are provided to explain embodiments, not limiting the present invention. Throughout this specification, the singular form includes the plural form unless the context clearly indicates otherwise. When terms “comprises” and/or “comprising” used herein do not preclude existence and addition of another component, step, operation and/or device, in addition to the above-mentioned component, step, operation and/or device.

Embodiments of the present invention may suitably comprise, consist or consist essentially of the elements disclosed and may be practiced in the absence of an element not disclosed. For example, it can be recognized by those skilled in the art that certain steps can be combined into a single step.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe the best method he or she knows for carrying out the invention.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method.

The singular forms “a,” “an,” and “the” include plural referents, unless the context clearly dictates otherwise.

As used herein and in the appended claims, the words “comprise,” “has,” and “include” and all grammatical variations thereof are each intended to have an open, non-limiting meaning that does not exclude additional elements or steps.

As used herein, the terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used. Occurrences of the phrase “according to an embodiment” herein do not necessarily all refer to the same embodiment.

Ranges may be expressed herein as from about one particular value, and/or to about another particular value. When such a range is expressed, it is to be understood that another embodiment is from the one particular value and/or to the other particular value, along with all combinations within said range.

Although the present invention has been described in detail, it should be understood that various changes, substitutions, and alterations can be made hereupon without departing from the principle and scope of the invention. Accordingly, the scope of the present invention should be determined by the following claims and their appropriate legal equivalents.

What is claimed is:

1. An apparatus for driving a motor, the apparatus comprising:
a rectifier configured to rectify an input voltage (AC) to generate a driving voltage;
a motor driver configured to apply the driving voltage to the respective phases of the motor through a switching operation; and
a controller configured to control a pulse width modulation (PWM) signal for controlling the switching operation of the motor driver, to decide whether or not driving of the motor is stopped depending on whether or not an over-voltage is generated in the input voltage based on an output voltage sensed by the rectifier and to decide whether or not the motor is again driven or whether or not the driving of the motor is completely stopped by deciding whether or not the input voltage returns to a normal voltage or whether or not the over-voltage is again generated within a predetermined time according to the number of generated over-voltages.

2. The apparatus for driving a motor of claim 1, wherein the rectifier comprises:
a rectifier circuit configured to generate the driving voltage through a smoothing capacitor and a bridge rectifier circuit; and
a voltage divider circuit configured to divide the driving voltage of the rectifier circuit through a resistor circuit to generate the output voltage.

3. The apparatus for driving a motor of claim 1, wherein the controller is further configured to decide whether or not the motor is again driven depending on whether or not the normal voltage is applied in the input voltage or whether or not the driving of the motor is completely stopped depending on whether or not the over-voltage is again generated within the predetermined time, according to a comparison result between the number of generated over-voltages and a preset reference number, in the case in which the over-voltage is generated, such that the driving of the motor is stopped.

4. The apparatus for driving a motor of claim 2, wherein the controller is further configured to compare a magnitude of the input voltage with that of a first preset reference voltage based on the output voltage and decides whether or not a time in which the input voltage is continuously applied is a first preset reference time or more in the case in which the magnitude of the input voltage is larger than that of the first preset reference voltage, thereby deciding whether or not the motor is stopped.

5. The apparatus for driving a motor of claim 3, wherein the controller is further configured to maintain a state in which the driving of the motor is stopped for a predetermined time and then decide whether or not the motor is again driven depending on a comparison result between the input voltage and a second preset reference voltage in the case in which the number of generated over-voltages is not larger than the preset reference number and decide whether or not the driving of the motor is completely stopped depending on whether or not the over-voltage is again generated within a second preset reference time in the case in which the number of generated over-voltages is larger than the preset reference number.

6. The apparatus for driving a motor of claim 5, wherein the controller is further configured to again drive the motor only in the case in which a predetermined input signal is applied from the outside, in the case in which the over-voltage is again generated within the second preset reference time.

7. The apparatus for driving a motor of claim 1, wherein the controller is further configured to control whether or not the motor is again driven or whether or not the driving of the motor is completely stopped through the PWM signal in the case in which the over-voltage is generated.

8. The apparatus for driving a motor of claim 1, wherein the controller comprises:
a PWM signal generating module configured to generate the PWM signal for controlling the switching operation of the motor driver; and
a controller configured to control whether or not the motor is again driven or whether or not the driving of the motor is completely stopped depending on whether or not the over-voltage is generated in the input voltage and whether or not the over-voltage is again generated within the predetermined time through a control of the PWM signal generating module.

9. A controlling method of an apparatus for driving a motor, the method comprising:
an over-voltage generation deciding step of deciding whether or not the driving of the motor is stopped depending on whether or not an over-voltage is generated in an input voltage based on an output voltage sensed by a rectifier;
a step of comparing the number of generated over-voltages with a preset reference number; and
a motor driving controlling step of controlling whether or not the motor is again driven or whether or not the driving of the motor is completely stopped by deciding whether or not the input voltage returns to a normal voltage or whether or not the over-voltage is again generated within a predetermined time depending on a comparison result between the number of generated over-voltages and the preset reference number.

10. The controlling method of an apparatus for driving a motor of claim 9, wherein the over-voltage generation deciding step comprises:
a step of generating a driving voltage by rectifying the input voltage through a smoothing capacitor and a bridge rectifier circuit; and
a step of sensing the output voltage by dividing the driving voltage through a resistor circuit.

11. The controlling method of an apparatus for driving a motor of claim 10, wherein the over-voltage generation deciding step comprises:
a step of comparing a magnitude of the input voltage with that of a first preset reference voltage based on the output voltage;
a step of deciding whether or not a time in which the input voltage is continuously applied is a first preset reference time or more in the case in which the magnitude of the input voltage is larger than that of the first preset reference voltage; and
a step of counting an over-voltage generation time and the number of generated over-voltages and stopping the driving of the motor in the case in which the time in which the input voltage is continuously applied is the first preset reference time or more.

12. The controlling method of an apparatus for driving a motor of claim 11, wherein the motor driving controlling step comprises:
a step of deciding whether or not the motor is again driven by comparing the input voltage with a second preset reference voltage in the case in which the number of generated over-voltages is smaller than the preset reference number; and
a step of deciding whether or not the driving of the motor is completely stopped by comparing the over-voltage generation time in which the over-voltage is again generated with a second preset reference time in the case in which the number of generated over-voltages is larger than the preset reference number.

13. The controlling method of an apparatus for driving a motor of claim 12, wherein the step of deciding whether or not the motor is again driven comprises:
a step of maintaining a state in which the driving of the motor is stopped for a predetermined time;
a step of comparing the input voltage with the second preset reference voltage based on the output voltage; and
a step of again driving the motor in the case in which the input voltage is smaller than the second preset reference voltage.

14. The controlling method of an apparatus for driving a motor of claim 13, wherein the step of deciding whether or not the driving of the motor is completely stopped comprises:
a step of comparing the over-voltage generation time with the second preset reference time; and
a step of deciding whether or not a predetermined input signal is applied from the outside in the case in which the over-voltage generation time is smaller than the second preset reference time.

15. The controlling method of an apparatus for driving a motor of claim 14, wherein the step of deciding whether or not the driving of the motor is completely stopped further includes, in the case in which the predetermined input signal is applied from the outside, comprises:
a step of initializing the number of generated over-voltages and the over-voltage generation time; and
again driving the motor.

16. The controlling method of an apparatus for driving a motor of claim 14, wherein the step of deciding whether or not the driving of the motor is completely stopped further includes, in the case in which the over-voltage generation time is larger than the second preset reference time, comprises:
a step of initializing the number of generated over-voltages and the over-voltage generation time;
a step of maintaining the state in which the driving of the motor is stopped for the predetermined time;
a step of deciding whether or not the motor is again driven by comparing the input voltage with that of the second preset reference voltage based on the output voltage; and
a step of again driving the motor in the case in which the input voltage is smaller than the second preset reference voltage.
